(19) United States
(12) Patent Application Publication
(10) Pub. No.: US 2019/0221666 A1
(43) Pub. Date: Jul. 18, 2019

(54) SEMICONDUCTOR DEVICE AND METHOD OF MANUFACTURING THE SAME

(71) Applicant: DB HITEK CO., LTD., Seoul (KR)

(72) Inventors: Ki Wan Bang, Chungcheongbuk-do (KR); Yang Hee Song, Gwangmyeong-si (KR)

(21) Appl. No.: 16/250,082

(22) Filed: Jan. 17, 2019

(30) Foreign Application Priority Data
Jan. 17, 2018 (KR) 10-2018-0006028

(51) Int. Cl. H01L 29/78; H01L 29/40; H01L 29/66; H01L 29/45

(52) U.S. Cl. CPC H01L 29/7816; H01L 29/402; H01L 29/45; H01L 29/401; H01L 29/66681

(57) ABSTRACT

A semiconductor device and a method of manufacturing the same are disclosed. The semiconductor device includes a drift region disposed in a surface portion of a substrate, a body region disposed on one side of the drift region, a gate structure disposed on a portion of the drift region and a portion of the body region, a source region disposed in a surface portion of the body region to be adjacent to the gate structure, a drain region disposed in a surface portion of the drift region to be spaced apart from the gate structure, an insulating layer pattern disposed on a portion of the gate structure and a second surface portion of the drift region between the gate structure and the drain region, and a floating electrode disposed on the insulating layer pattern to reduce an electric field in the drift region.

### CROSS-REFERENCE TO RELATED APPLICATION

This application claims the priority benefit of Korean Patent Application No. 10-2018-0006028, filed on Jan. 17, 2018, and all the benefits accruing therefrom under 35 U.S.C. § 119, the contents of which are incorporated by reference in their entirety.

### TECHNICAL FIELD

The present disclosure relates to a semiconductor device and a method of manufacturing the same. More specifically, the present disclosure relates to a high voltage semiconductor device such as a laterally double diffused metal oxide semiconductor (LDMOS) device and a method of manufacturing the same.

### BACKGROUND

LDMOS devices may include a field plate disposed between a gate electrode and a drain region and made of silicon oxide. The field plate may be used to increase the breakdown voltage of the LDMOS device. Further, LDMOS devices may include a drift region disposed under the gate electrode. The field plate and the drain region may be formed in the drift region. In some cases, the field plate may be formed by a local oxidation of silicon (LOCOS) process or a shallow trench isolation (STI) process.

Such field plates, however, increase the distance that electrons must move, resulting in the ON-state resistance (Rₛₚ) of the LDMOS device being undesirably increased.

### SUMMARY

The present disclosure provides a semiconductor device having reduced ON-state resistance and improved breakdown voltage, and a method of manufacturing the same.

In accordance with an aspect of the present disclosure, a semiconductor device may include a drift region disposed in a first surface portion of a substrate, a body region disposed in a second surface portion of the substrate, spaced apart from the drift region, a gate structure disposed on a first portion of the drift region and a portion of the body region, a source region disposed in a surface portion of the body region adjacent to the gate structure, a drain region disposed in a second surface portion of the drift region spaced apart from the gate structure, an insulating layer pattern disposed on a portion of the gate structure and a third surface portion of the drift region between the gate structure and the drain region, and a floating electrode disposed on the insulating layer pattern to reduce an electric field in the drift region.

In accordance with some embodiments of the present disclosure, the semiconductor device may further include a first contact plug disposed on the source region and a second contact plug disposed on the drain region, and wherein the floating electrode may be made of the same material as the contact plugs.

In accordance with some embodiments of the present disclosure, the insulating layer pattern may be made of silicon oxide or silicon nitride.

In accordance with some embodiments of the present disclosure, the gate structure may include a gate insulating layer, a gate electrode disposed on the gate insulating layer and a gate spacer disposed adjacent to the gate insulating later and the gate electrode, and the insulating layer pattern is disposed on a portion of the gate electrode, a portion of the gate spacer and the second surface portion of the drift region.

In accordance with some embodiments of the present disclosure, the semiconductor device may further include an insulating layer disposed on the substrate, and the floating electrode may be buried in the insulating layer.

In accordance with some embodiments of the present disclosure, the semiconductor device may further include a field plate disposed on the drift region and made of an insulating material. In such a case, a portion of the gate structure may be disposed on a first portion of the field plate. Further, the insulating layer pattern may be disposed on the portion of the gate structure and a second portion of the field plate.

In accordance with some embodiments of the present disclosure, the semiconductor device may further include an etch stop layer pattern disposed on the insulating layer pattern, and the floating electrode may be disposed on the etch stop layer pattern. In such a case, the insulating layer pattern may be made of silicon oxide, and the etch stop layer pattern may be made of silicon nitride.

In accordance with another aspect of the present disclosure, a method of manufacturing a semiconductor device may include forming a drift region in a first surface portion of a substrate, forming a body region in a second surface portion of the substrate, spaced apart from the drift region, forming a gate structure on a first surface portion of the drift region and a portion of the body region, forming a source region in a surface portion of the body region adjacent to the gate structure, forming a drain region in a second surface portion of the drift region to be spaced apart from the gate structure, forming an insulating layer pattern on a portion of the gate structure and a third surface portion of the drift region between the gate structure and the drain region, and forming a floating electrode on the insulating layer pattern to reduce an electric field in the drift region.

In accordance with some embodiments of the present disclosure, forming the floating electrode may include forming an insulating layer on the substrate such that the gate structure and the insulating layer pattern are buried, partially removing the insulating layer to define an opening exposing the insulating layer pattern, forming a metal layer on the insulating layer such that the opening is filled with a metallic material, and partially removing the metal layer such that the insulating layer is exposed thereby forming the floating electrode in the opening.

In accordance with some embodiments of the present disclosure, the method may further include partially removing the insulating layer to define contact holes exposing the source region and the drain region before forming the metal layer. In such a case, the contact holes may be filled with the metallic material when the metal layer is formed, such that contact plugs may be formed in the contact holes simultaneously with the floating electrode.

In accordance with some embodiments of the present disclosure, the floating electrode and the contact plugs may be made of tungsten.

In accordance with some embodiments of the present disclosure, the insulating layer pattern may be made of silicon nitride, and the insulating layer may be made of silicon oxide.

In accordance with some embodiments of the present disclosure, the method may further include forming an insulating layer on the substrate and forming a conductive layer on the insulating layer, and the insulating layer pattern and the floating electrode may be formed by patterning the insulating layer and the conductive layer.

In accordance with some embodiments of the present disclosure, the method may further include forming an insulating layer on the substrate such that the floating electrode is buried.

In accordance with some embodiments of the present disclosure, the method may further include forming a field plate on the drift region. At this time, the field plate may be made of an insulating material, and the portion of the gate structure may be formed on a portion of the field plate. Further, the insulating layer pattern may be formed on the portion of the gate structure and another portion of the field plate.

In accordance with some embodiments of the present disclosure, the method may further include forming an etch stop layer pattern on the insulating layer pattern, and the floating electrode may be formed on the etch stop layer pattern. In such case, the insulating layer pattern may be made of silicon oxide, and the etch stop layer pattern may be made of silicon nitride.

The above summary of the present disclosure is not intended to describe each illustrated embodiment or every implementation of the present disclosure. The detailed description and claims that follow more particularly describe these embodiments.

### BRIEF DESCRIPTION OF THE DRAWINGS

Exemplary embodiments can be understood in more detail from the following description taken in conjunction with the accompanying drawings, in which:

FIG. 1 is a schematic cross-sectional view illustrating a semiconductor device in accordance with an embodiment of the present disclosure;

FIG. 2 is a schematic cross-sectional view illustrating a semiconductor device in accordance with another embodiment of the present disclosure;

FIG. 3 is a schematic cross-sectional view illustrating a semiconductor device in accordance with still another embodiment of the present disclosure;

FIGS. 4 to 8 are schematic cross-sectional views illustrating a method of manufacturing the semiconductor device of FIG. 1;

FIGS. 9 and 10 are schematic cross-sectional views illustrating a method of manufacturing the semiconductor device of FIG. 2; and

FIGS. 11 to 14 are schematic cross-sectional views illustrating a method of manufacturing the semiconductor device of FIG. 3.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms such as a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

FIG. 1 is a schematic cross-sectional view illustrating a semiconductor device in accordance with an exemplary embodiment of the present disclosure.

Referring to FIG. 1, a semiconductor device 100, in accordance with an exemplary embodiment of the present disclosure, may include a drift region 106 disposed in a surface portion of a substrate 102, a body region 108 disposed in the surface portion of the substrate 102 and spaced apart from the drift region 106, a gate structure 110 disposed on a portion of the drift region 106 and a portion of the body region 108, a drain region 120 disposed in a first surface portion of the drift region 106 and spaced apart from the gate structure 110, and a source region 130 disposed in a surface portion of the body region 108 and adjacent to the gate structure 110. Particularly, the semiconductor device 100 may include an insulating layer pattern 140 disposed on a portion of the gate structure 110 and a second surface portion of the drift region 106 between the gate structure 110 and the drain region 120, and a floating electrode 160 disposed on the insulating layer pattern 140 to reduce an electric field in the drift region 106.

In embodiments, a p-type substrate may be used as the substrate 102. Alternatively, a p-type epitaxial layer may be disposed on the substrate 102. In such a case, the drift region 106 and the body region 108 may be formed in surface portions of the p-type epitaxial layer.

The drift region 106 may be an n-type impurity region, and the drain region 120 may be a high concentration n-type impurity region having a relatively high impurity concentration. The body region 108 may be a p-type impurity region, and the source region 130 may be a high concentration n-type impurity region. Further, a high concentration p-type impurity region 132 functioning as a body contact region may be disposed on one side of the source region 130, a low concentration n-type impurity region 134 may be disposed on another side of the source region 130.

In accordance with the present embodiment, the floating electrode 160 may reduce the electric field in the drift region 106, and thus the breakdown voltage of the semiconductor device 100 may be improved. Further, because no field plate (formed by a LOCOS process or a STI process) is used, the ON-state resistance of the semiconductor device 100 may be reduced as compared to conventional devices.

The gate structure 110 may include a gate insulating layer 112 disposed on the substrate 102, a gate electrode 114 disposed on the gate insulating layer 112, and a gate spacer 116 disposed on side surfaces of the gate electrode 114 and the gate insulating layer 112. The gate spacer 116 may therefore at least partially surround the gate insulating layer 112 and the gate electrode 114. The insulating layer pattern 140 may be disposed on a portion of the gate electrode 114, a portion of the gate spacer 116, and a second surface portion of the drift region 106 between the gate spacer 116 and the drain region 120. The insulating layer pattern 140 may function as a silicide blocking pattern and prevent metal silicide from being formed on the second surface portion of the drift region 106 during the forming of metal silicide layers (not shown) on the drain region 120 and the source region 130. The metal silicide layers may be formed by a metal silicidation process, and, for example, cobalt silicide layers may be formed on the drain region 120 and the source region 130.

The semiconductor device 100 may include contact plugs 162 disposed on portions of the drain region 120, the source region 130, and body contact region 132. The floating electrode 160 may be made of the same material as the contact plugs 162. For example, an insulating layer 150 made of silicon oxide may be disposed on the substrate 102, and the contact plugs 162 may be connected with the drain region 120 and the source region 130 through the insulating layer 150. In embodiments, the insulating layer 150 may have an opening 152 (as depicted in FIG. 8) exposing the insulating layer pattern 140, and the floating electrode 160 may be disposed in the opening 152. In embodiments the insulating layer pattern 140 may be made of silicon nitride having an etch selectivity to silicon oxide, and the floating electrode 160 and the contact plugs 162 may be made of tungsten.

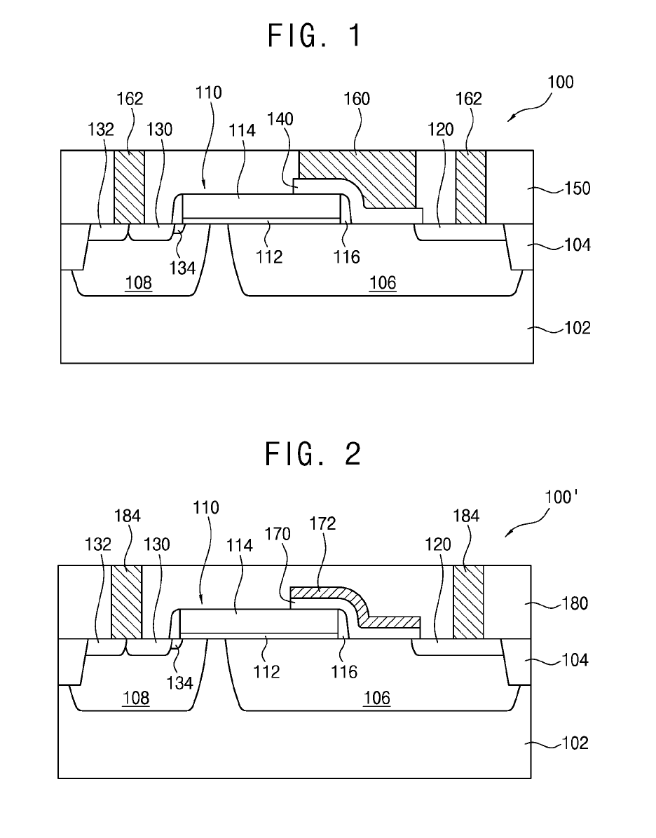

FIG. 2 is a schematic cross-sectional view illustrating a semiconductor device in accordance with another embodiment of the present disclosure.

Referring to FIG. 2, a semiconductor device 100′, in accordance with another embodiment of the present disclosure, may include a drift region 106 and a body region 108 disposed in surface portions of a substrate 102, a gate structure 110 disposed on the substrate 102, a drain region 120 disposed in a surface portion of the drift region 106, and a source region 130 disposed in a surface portion of the body region 108. Further, the semiconductor device 100′ may include an insulating layer pattern 170 disposed on a portion of the gate structure 110 and a surface portion of the drift region 106, and a floating electrode 172 disposed on the insulating layer pattern 170.

In accordance with the present embodiment, the insulating layer pattern 170 may be conformally formed on the portion of the gate electrode 114 and the surface portion of the drift region 106 and may have a substantially constant thickness. Further, the floating electrode 172 may be conformally formed on the insulating layer pattern 170 and may have a substantially constant thickness. In embodiments, an insulating layer (not shown) and a conductive layer (not shown) may be conformally formed on the substrate 102 and the gate structure 110, and the insulating layer pattern 170 and the floating electrode 172 may then be formed by patterning the insulating layer and the conductive layer. The insulating layer pattern 170 may be made of silicon oxide, and the floating electrode 172 may be made of impurity doped polysilicon or a metallic material such as aluminum, tungsten, or the like.

Further, the semiconductor device 100′ may include an insulating layer 180 disposed on the substrate 102, in which the gate structure 110, the insulating layer pattern 170 and the floating electrode 172 are buried, and contact plugs 184 connected with the drain region 120 and the source region 130 through the insulating layer 180.

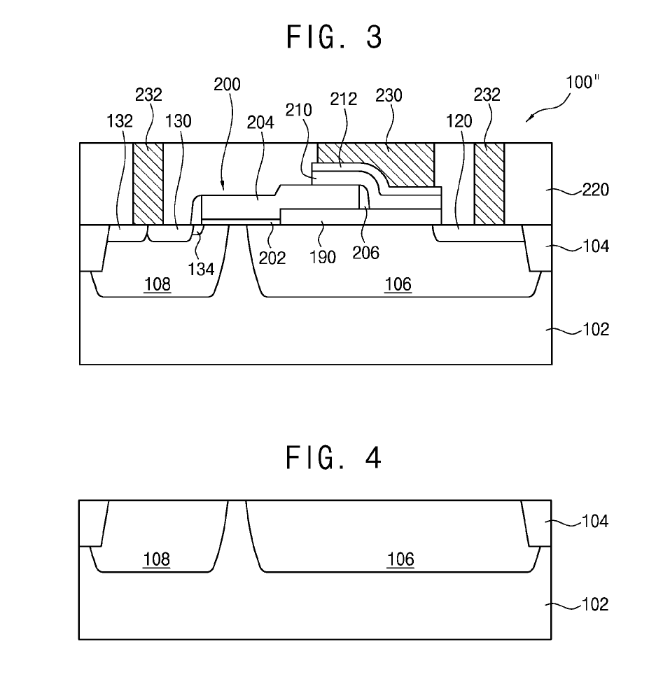

FIG. 3 is a schematic cross-sectional view illustrating a semiconductor device in accordance with still another embodiment of the present disclosure.

Referring to FIG. 3, a semiconductor device 100″, in accordance with another embodiment of the present disclosure, may include a drift region 106 and a body region 108 disposed in surface portions of a substrate 102, a gate structure 200 disposed on the substrate 102, a drain region 120 disposed in a surface portion of the drift region 106, and a source region 130 disposed in a surface portion of the body region 108. Further, a body contact region 132 may be formed on one side of the source region 130. The semiconductor device 100″ may include a field plate 190 disposed on the drift region 106, and a portion of the gate structure 200 may be disposed on a portion of the field plate 190. Further, the semiconductor device 100″ may include an insulating layer pattern 210 disposed on the portion of the gate structure 200 and another portion of the field plate 190, an etch stop layer pattern 212 disposed on the insulating layer pattern 210, and a floating electrode 230 disposed on the etch stop layer pattern 212.

In accordance with the present embodiment, the field plate 190 may be made of silicon oxide and may be used to improve the breakdown voltage of the semiconductor device 100″. For example, a silicon oxide layer may be formed on the substrate 102 by a chemical vapor deposition (CVD) process, and the field plate 190 may then be formed by patterning the silicon oxide layer. Thus, the ON-state resistance of the semiconductor device 100″ may be significantly reduced as compared to the conventional devices in which the field plate is formed by a LOCOS process or a STI process.

The gate structure 200 may include a gate insulating layer 202, a gate electrode 204 disposed on the gate insulating layer 202 and the portion of the field plate 190, and a gate spacer 206 disposed on side surfaces of the gate electrode 204. The insulating layer pattern 210 and the etch stop layer pattern 212 may be conformally formed on the portion of the gate structure 200 and another portion of the field plate 190. For example, an insulating layer (not shown) and an etch stop layer (not shown) may be conformally formed on the substrate on which the field plate 190 and the gate structure 200 are formed, and the insulating layer pattern 210 and the etch stop layer pattern 212 may then be formed by patterning the insulating layer and the etch stop layer. In embodiments, the insulating layer pattern 210 may be made of silicon oxide and the etch stop layer pattern 212 may be made of silicon nitride.

Further, the semiconductor device 100″ may include contact plugs 232 disposed on the drain region 120, the source region 130, and the body contact region 132. The floating electrode 230 may be made of the same material as the contact plugs 232. For example, an insulating layer 220 made of silicon oxide may be disposed on the substrate 102, and the contact plugs 232 may be connected with the drain region 120 and the source region 130 through the insulating layer 220. Particularly, the insulating layer 220 may have an opening 222 (as depicted in FIG. 14) exposing the etch stop layer pattern 212, and the floating electrode 230 may be disposed in the opening 222. In embodiments, the floating electrode 230 and the contact plugs 232 may be made of tungsten.

FIGS. 4 to 8 are schematic cross-sectional views illustrating a method of manufacturing the semiconductor device as depicted and described with respect to FIG. 1.

Referring to FIG. 4, isolation regions 104 for defining an active region may be formed in surface portions of a substrate 102, and a drift region 106 and a body region 108 may then be formed in surface portions of the active region by an ion implantation process. The drift region 106 and the body region 108 may be formed adjacent to each other.

A p-type substrate may be used as the substrate 102. Alternatively, a p-type epitaxial layer may be formed on the substrate 102. In such case, the drift region 106 and the body region 108 may be formed in surface portions of the p-type epitaxial layer. The drift region 106 may be an n-type impurity region, and the body region 108 may be a p-type impurity region.

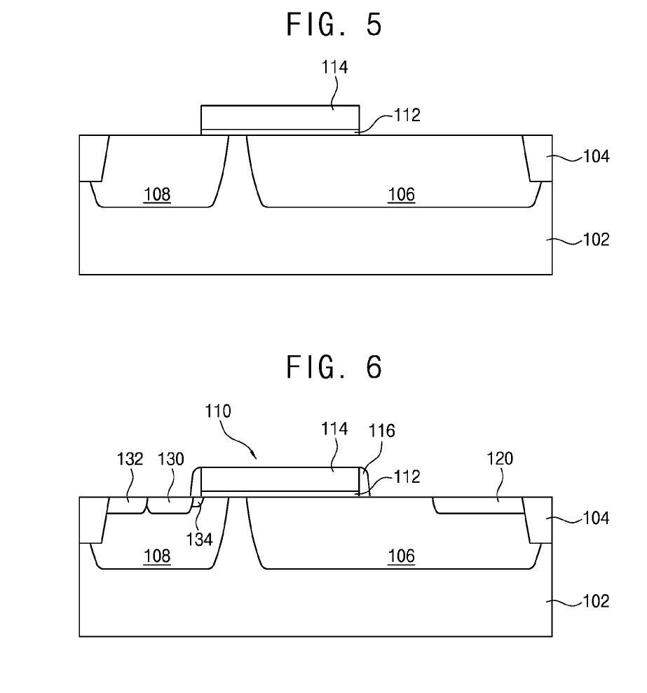

Referring to FIG. 5, a gate insulating layer 112 and a gate electrode 114 may be formed on the substrate 102. Particularly, the gate insulating layer 112 and the gate electrode 114 may be formed on a portion of the drift region 106 and a portion of the body region 108. For example, a silicon oxide layer may be formed by a thermal oxidation process and a conductive layer, e.g., an impurity-doped polysilicon layer may be formed on the silicon oxide layer. The gate insulating layer 112 and the gate electrode 114 may be formed by patterning the silicon oxide layer and the impurity doped polysilicon layer.

Referring to FIG. 6, a gate spacer 116 may be formed on side surfaces of the gate electrode 114. In embodiments, the gate spacer 116 may be formed of silicon oxide or silicon nitride.

Then, a drain region 120 may be formed in a surface portion of the drift region 106 and a source region 130 may be formed in a surface portion of the body region 108. The drain region 120 and the source region 130 may be high concentration n-type impurity regions and may be simultaneously formed by an ion implantation process. Particularly, the drain region 120 may be formed to be spaced apart from the gate structure 110, and the source region 130 may be formed to be adjacent to the gate structure 110.

Further, a body contact region 132 may be formed on one side of the source region 130. The body contact region 132 may be a high concentration p-type impurity region and may be formed by an ion implantation process. Still further, a low concentration n-type impurity region 134 may be formed on another side of the source region 130. In embodiments, the low concentration n-type impurity region 134 may be formed before forming the gate spacer 116.

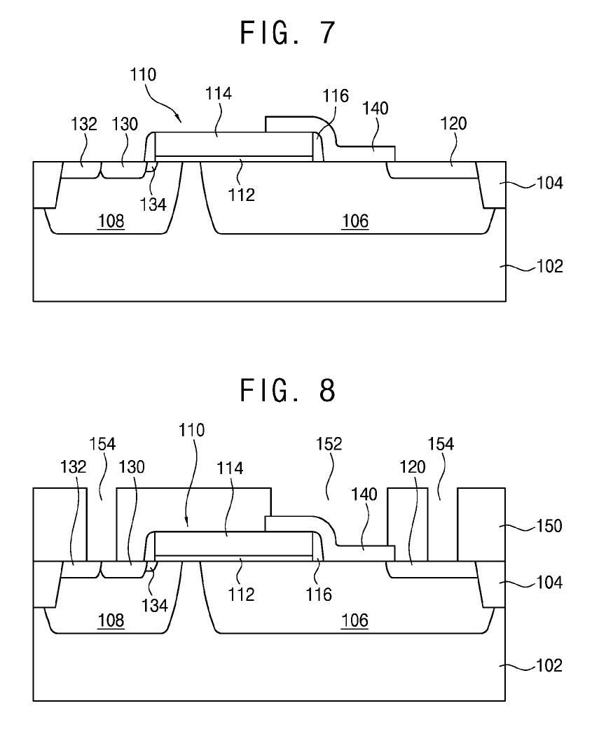

Referring to FIG. 7, an insulating layer pattern 140 may be formed on a portion of the gate structure 110 and a second surface portion of the drift region 106 between the gate structure 110 and the drain region 120. That is, the insulating layer pattern 140 may be formed on a portion of the gate electrode 114, a portion of the gate spacer 116 and a second surface portion of the drift region 106 adjacent to the gate spacer 116. For example, an insulating layer (not shown) may be formed on the substrate 102 such that the gate structure 110 is buried therein, and the insulating layer pattern 140 may then be formed by patterning the insulating layer.

Though not shown in figures, after forming the insulating layer pattern 140, a metal silicidation process may be performed to form ohmic contacts on the drain region 120 and the source region 130. Particularly, the insulating layer pattern 140 may function as a silicide blocking pattern for preventing metal silicide from being formed on the second surface portion of the drift region 106 during the metal silicidation process.

Referring to FIG. 8, an insulating layer 150 may be formed on the substrate 102 such that the gate structure 110 and the insulating layer pattern 140 are buried therein. Then, an opening 152 and contact holes 154 may be formed by partially etching the insulating layer 150 so that the insulating layer pattern 140 and the drain and source regions 120 and 130 are at least partially exposed. At this time, it is preferable that the insulating layer pattern 140 has an etch selectivity with respect to the insulating layer 150 so that the insulating layer pattern 140 is not removed while the insulating layer 150 is partially etched. For example, the insulating layer pattern 140 may be made of silicon nitride and the insulating layer 150 may be made of silicon oxide.

Then, a floating electrode 160 and contact plugs 162 may be formed in the opening 152 and the contact holes 154, respectively, as shown in FIG. 1. For example, a metal layer (not shown) may be formed on the substrate 102 such that the opening 152 and the contact holes 154 are filled with a metallic material, and the floating electrode 160 and the contact plugs 162 may then be formed by partially removing the metal layer. For example, the metal layer may be partially removed by a chemical mechanical polish (CMP) process until the insulating layer 150 is exposed.

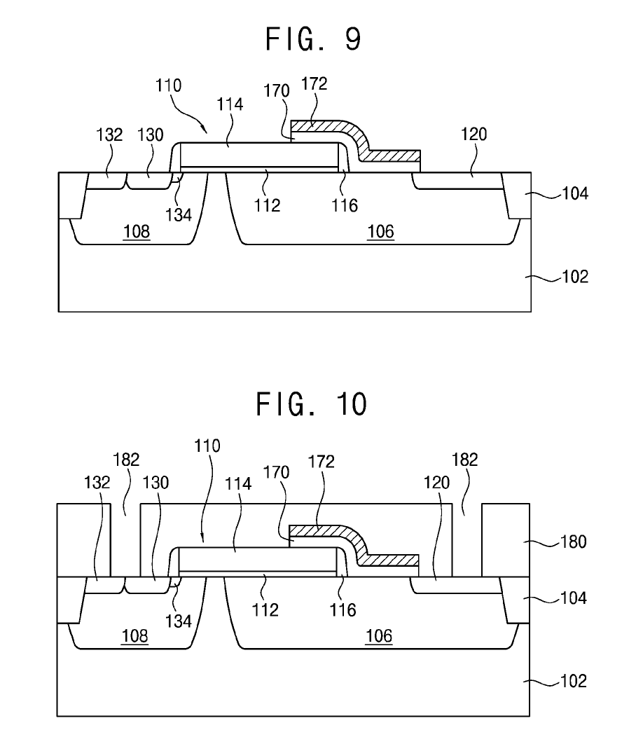

FIGS. 9 and 10 are schematic cross-sectional views illustrating a method of manufacturing the semiconductor device as depicted and described with respect to FIG. 2.

Referring to FIG. 9, after forming the gate structure 110 and the drain and source regions 120 and 130, an insulating layer pattern 170 and a floating electrode 172 may be formed on a portion of the gate structure 110 and a second surface portion of the drift region 106 between the gate structure 110 and the drain region 120.

For example, an insulating layer (not shown) and a conductive layer (not shown) may be formed on the substrate 102, and the insulating layer pattern 170 and the floating electrode 172 may then be formed by patterning the insulating layer and the conductive layer. At this time, the insulating layer and the conductive layer may be conformally formed along the surface profiles of the substrate 102 and the gate structure 110. In embodiments, the insulating layer pattern 170 may be formed of silicon oxide, and the floating electrode 172 may be formed of an impurity doped polysilicon or a metallic material such as aluminum, tungsten, or the like.

Referring to FIG. 10, an insulating layer 180, e.g., a silicon oxide layer, may be formed on the substrate 102 such that the gate structure 110 and the floating electrode 172 are buried therein, and contact holes 182 may then be formed to expose the drain region 120 and the source region 130 by partially removing the insulating layer 180. Then, contact plugs 184 may be formed in the contact holes 182 as shown in FIG. 2.

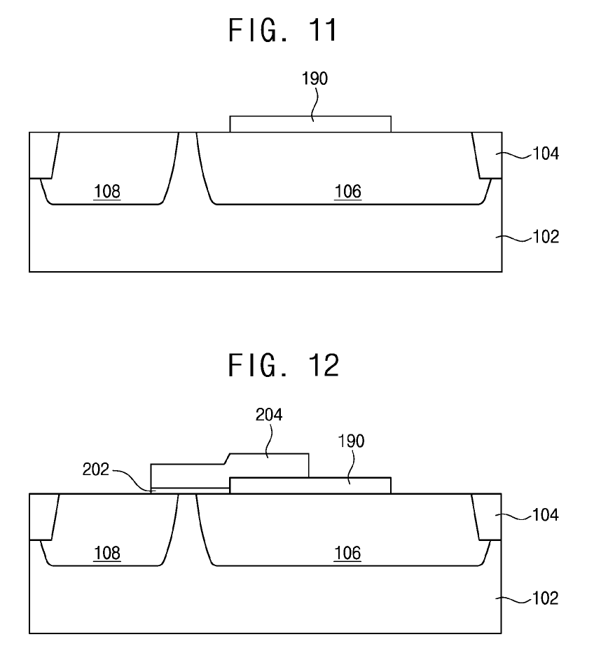

FIGS. 11 to 14 are schematic cross-sectional views illustrating a method of manufacturing the semiconductor device as depicted and described with respect to FIG. 3.

Referring to FIG. 11, isolation regions 104 for defining an active region may be formed in surface portions of a substrate 102, and a drift region 106 and a body region 108 may then be formed in surface portions of the active region by an ion implantation process. The drift region 106 and the body region 108 may be formed adjacent to each other.

Then, a field plate 190 may be formed on the drift region 106. For example, an insulating layer (not shown), e.g., a silicon oxide layer, may be formed on the substrate 102 by a CVD process, and the field plate 190 may then be formed by patterning the insulating layer.

Referring to FIG. 12, a gate insulating layer 202 and a gate electrode 204 may be formed on the substrate 102 and the field plate 190. For example, a silicon oxide layer may be formed by a thermal oxidation process and a conductive layer, e.g., an impurity doped polysilicon layer may be formed on the silicon oxide layer and the field plate 190. The gate insulating layer 202 and the gate electrode 204 may be formed by patterning the silicon oxide layer and the impurity doped polysilicon layer. Particularly, the gate electrode 204 may be formed on the gate insulating layer 202 and a portion of the field plate 190 as shown in FIG. 12.

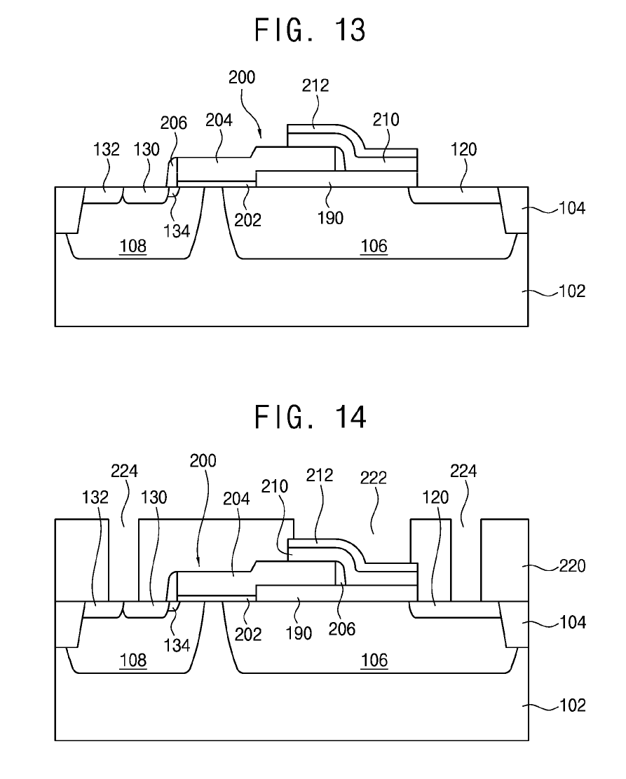

Referring to FIG. 13, a gate spacer 206 may be formed on side surfaces of the gate electrode 204 thereby forming a gate structure 200. For example, the gate spacer 206 may be formed on silicon oxide or silicon nitride. Further, a drain region 120 may be formed in a surface portion of the drift region 106 and a source region 130 may be formed in a surface portion of the body region 108. The drain region 120 and the source region 130 may be high concentration n-type impurity regions and may be simultaneously formed by an ion implantation process. Particularly, the drain region 120 may be formed to be adjacent to the field plate 190, and the source region 130 may be formed to be adjacent to the gate structure 200 as shown in FIG. 13.

Further, a body contact region 132 may be formed on one side of the source region 130. The body contact region 132 may be a high concentration p-type impurity region and may be formed by an ion implantation process. Still further, a low concentration n-type impurity region 134 may be formed on another side of the source region 130. The low concentration n-type impurity region 134 may be formed before forming the gate spacer 206.

Then, an insulating layer pattern 210 and an etch stop layer pattern 212 may be formed on a portion of the gate structure 200 and another portion of the field plate 190 adjacent to the gate structure 200. For example, a silicon oxide layer and a silicon nitride layer may be formed on the substrate 102, and the insulating layer pattern 210 and the etch stop layer pattern 212 may be formed by patterning the silicon oxide layer and the silicon nitride layer.

Referring to FIG. 14, an insulating layer 220 may be formed on the substrate 102 such that the gate structure 200 and the etch stop layer pattern 212 are buried therein. Then, an opening 222 and contact holes 224 may be formed by partially etching the insulating layer 220 such that the etch stop layer pattern 212 and the drain and source regions 120 and 130 are exposed. At this time, it is preferable that the etch stop layer pattern 212 be made of silicon nitride and has an etch selectivity with respect to the insulating layer 220. For example, the insulating layer 220 may be made of silicon oxide.

Then, a floating electrode 230 and contact plugs 232 may be formed in the opening 222 and the contact holes 224, respectively, as shown in FIG. 3. For example, a metal layer (not shown) may be formed on the substrate 102 such that the opening 222 and the contact holes 224 are filled with a metallic material, and the floating electrode 230 and the contact plugs 232 may then be formed by partially removing the metal layer. For example, the metal layer may be partially removed by a CMP process until the insulating layer 220 is exposed.

Although the semiconductor device 100 and the method of manufacturing the semiconductor device 100 have been described with reference to specific embodiments, they are not limited thereto. Therefore, it will be readily understood by those skilled in the art that various modifications and changes can be made thereto without departing from the spirit and scope of the present disclosure defined by the appended claims.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that embodiments may comprise fewer features than illustrated in any individual embodiment described above. The embodiments described herein are not meant to be an exhaustive presentation of the ways in which the various features may be combined. Accordingly, the embodiments are not mutually exclusive combinations of features; rather, embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Moreover, reference in the specification to “one embodiment,” “an embodiment,” or “some embodiments” means that a particular feature, structure, or characteristic, described in connection with the embodiment, is included in at least one embodiment of the teaching. The appearances of the phrase “in one embodiment” in various places in the specification are not necessarily all referring to the same embodiment.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of Section 112, sixth paragraph of 35 U.S.C. are not to be invoked unless the specific terms “means for” or “step for” are recited in a claim.

What is claimed is:

1. A semiconductor device comprising:
a drift region disposed in a first surface portion of a substrate;
a body region disposed in a second surface portion of the substrate, spaced apart from the drift region;
a gate structure disposed on a first surface portion of the drift region and a portion of the body region;
a source region disposed in a surface portion of the body region adjacent to the gate structure;
a drain region disposed in a second surface portion of the drift region spaced apart from the gate structure;
an insulating layer pattern disposed on a portion of the gate structure and a third surface portion of the drift region between the gate structure and the drain region; and
a floating electrode disposed on the insulating layer pattern to reduce an electric field in the drift region.

2. The semiconductor device of claim 1, further comprising a first contact plug disposed on the source region and a second contact plug disposed on the drain region; and
wherein the floating electrode is made of the same material as the first contact plug and the second contact plug.

3. The semiconductor device of claim 2, wherein the insulating layer pattern is made of silicon oxide or silicon nitride.

4. The semiconductor device of claim 1, wherein the gate structure comprises a gate insulating layer, a gate electrode disposed on the gate insulating layer and a gate spacer disposed on side surfaces of the gate electrode, and
the insulating layer pattern is disposed on a portion of the gate electrode, a portion of the gate spacer and the second surface portion of the drift region.

5. The semiconductor device of claim 1, further comprising an insulating layer disposed on the substrate,
wherein the floating electrode is buried in the insulating layer.

6. The semiconductor device of claim 1, further comprising a field plate disposed on the drift region and made of an insulating material,
wherein a portion of the gate structure is disposed on a first portion of the field plate.

7. The semiconductor device of claim 6, wherein the insulating layer pattern is disposed on the portion of the gate structure and a second portion of the field plate.

8. The semiconductor device of claim 1, further comprising an etch stop layer pattern disposed on the insulating layer pattern,
wherein the floating electrode is disposed on the etch stop layer pattern.

9. The semiconductor device of claim 8, wherein the insulating layer pattern is made of silicon oxide, and the etch stop layer pattern is made of silicon nitride.

10. A method of manufacturing a semiconductor device, the method comprising:
forming a drift region in a first surface portion of a substrate;
forming a body region in a second surface portion of the substrate, spaced apart from the drift region;
forming a gate structure on a first surface portion of the drift region and a portion of the body region;
forming a source region in a surface portion of the body region adjacent to the gate structure;
forming a drain region in a second surface portion of the drift region spaced apart from the gate structure;
forming an insulating layer pattern on a portion of the gate structure and a third surface portion of the drift region between the gate structure and the drain region; and
forming a floating electrode on the insulating layer pattern to reduce an electric field in the drift region.

11. The method of claim 10, wherein forming the floating electrode comprises:
forming an insulating layer on the substrate such that the gate structure and the insulating layer pattern are buried;
partially removing the insulating layer to define an opening exposing the insulating layer pattern;
forming a metal layer on the insulating layer such that the opening is filled with a metallic material; and
partially removing the metal layer such that the insulating layer is exposed thereby forming the floating electrode in the opening.

12. The method of claim 11, further comprising partially removing the insulating layer to define contact holes exposing the source region and the drain region before forming the metal layer, and
wherein the contact holes are filled with the metallic material when the metal layer is formed, such that contact plugs are formed in the contact holes simultaneously with the forming of the floating electrode.

13. The method of claim 12, wherein the floating electrode and the contact plugs are made of tungsten.

14. The method of claim 11, wherein the insulating layer pattern is made of silicon nitride and the insulating layer is made of silicon oxide.

15. The method of claim 10, further comprising:
forming an insulating layer on the substrate; and
forming a conductive layer on the insulating layer,
wherein the insulating layer pattern and the floating electrode are formed by patterning the insulating layer and the conductive layer.

16. The method of claim 10, further comprising forming an insulating layer on the substrate such that the floating electrode is buried.

17. The method of claim 10, further comprising forming a field plate on the drift region,
wherein the field plate is made of an insulating material, and a portion of the gate structure is formed on a portion of the field plate.

18. The method of claim 17, wherein the insulating layer pattern is formed on the portion of the gate structure and a second portion of the field plate.

19. The method of claim 10, further comprising forming an etch stop layer pattern on the insulating layer pattern,
wherein the floating electrode is formed on the etch stop layer pattern.

20. The method of claim 19, wherein the insulating layer pattern is made of silicon oxide, and the etch stop layer pattern is made of silicon nitride.
